(19) United States
(12) Patent Application Publication
(10) Pub. No.: US 2010/0265665 A1
(43) Pub. Date: Oct. 21, 2010

(54) ELECTRONIC DEVICE HAVING A HEAT SINK

(76) Inventors: Yukihiro Kozaka, Kyoto (JP); Nobuyuki Koutani, Osaka (JP); Hiroyuki Imamura, Osaka (JP); Masanori Minamio, Osaka (JP)

Correspondence Address: MCDERMOTT WILL & EMERY LLP, 600 13TH STREET, NW, WASHINGTON, DC, 20005-3096, US

(21) Appl. No.: 12/760,219

(22) Filed: Apr. 14, 2010

(30) Foreign Application Priority Data
Apr. 15, 2009 (JP) 2009-099435
Apr. 1, 2010 (JP) 2010-085255

(51) Int. Cl. H05K 7/20

(52) U.S. Cl. 361/717

(57) ABSTRACT

The electronic device includes: a heat sink including a front surface having a concave portion; a heat conductive component placed in the concave portion, in contact with the heat sink; a semiconductor element placed in the concave portion, in contact with the heat conductive component; a flexible base plate electrically connected to the semiconductor element and placed on the surface of the heat sink; and a chassis member having a front surface on which the heat sink is fixed so as to come in contact with the heat sink at the back surface opposite to the front surface.

### FURTHER INFORMATION ABOUT TECHNICAL BACKGROUND TO THIS APPLICATION

This application claims foreign priority of Japanese Patent Application No. 2009-099435 filed on Apr. 15, 2009, and Japanese Patent Application No. 2010-085255 filed on Apr. 1, 2010, the entire of which including specification, drawings and claims is incorporated herein by reference.

### BACKGROUND OF THE INVENTION

(1) Field of the Invention

The present disclosure relates to electronic devices mounted with a semiconductor element, and in particular to an electronic device which has an increased efficiency in dissipating heat from the semiconductor element.

(2) Description of the Related Art

Semiconductor elements, which allow a large current to flow, generate a great amount of heat in some cases, and thus measures to dissipate heat are important. For example, the heat dissipation structure of an electronic device including a driving circuit formed in a plasma display apparatus will be described with reference to FIGS. 17 and 18 (refer to Patent Literature 1).

FIG. 17 is a sectional view of the electronic device viewed from a lateral side and disclosed in Patent Literature 1. FIG. 18 is a plain view of the same electronic device viewed from the above.

The electronic device includes: a semiconductor element 1; a heat sink 2 having a concave portion 2a; a heat conductive component 3; chassis member 4 in which a boss portion 4a is formed; and a flexible wiring board 35 having terminals 8a and 8b.

The semiconductor element 1 is an element for supplying display data to address electrodes. When displaying an image, high voltages are applied to the semiconductor element 1 so that a high electrical current flows. Since this causes a high temperature in the semiconductor element 1, measures to dissipate heat are taken as described below. That is, an inside of the concave portion 2a of the heat sink 2 is filled with the heat conductive component 3 and the semiconductor element 1 is arranged in the inside of the concave portion 2a to come in contact with the heat conductive component 3. This structure allows heat generated in the semiconductor element 1 to be conducted through the heat conductive component 3 to the heat sink 2 and further to the chassis member 4 fixing the heat sink 2, so that the heat generated in the semiconductor element 1 can be transferred to the entire heat dissipating plate 2 and the temperature of the semiconductor element 1 can be decreased effectively.

[Patent Reference 1] Japanese Unexamined Patent Application Publication No. 2005-338706

### SUMMARY OF THE INVENTION

The heat dissipation structure of the electronic device disclosed in Patent Reference 1, however, involves problems (1) to (3) described below.

(1) There is only a single main route for dissipating heat, which is the one conducting heat from the back side of the semiconductor element that is a heat source, through the heat conductive component to the heat sink. However, due to the tendency toward further miniaturizing the heat sink and the semiconductor element according to narrowing the frame of a set, it is not possible to sufficiently dissipate heat with the heat dissipation structure disclosed by Patent Reference 1.

(2) Heat conduction from the semiconductor element through the heat conductive component to the heat sink is unstable. As a result, there is a possibility of malfunction of the semiconductor element. To ensure stable heat conduction from the semiconductor element through the heat conductive component to the heat sink, stable contact between the semiconductor element and the heat conductive component is significantly important. However, merely making the heat conductive component abutted to the semiconductor element does not facilitate heat conduction, because the thickness of the heat conductive component abutting to the semiconductor element varies between each product, and heat resistance increases when the thickness increases. This can lead to malfunction of the semiconductor element in some cases.

(3) A metal plate (heat sink) is bonded with a heat-resistant double-faced adhesive tape to the flexible wiring board, and bonding strength of the double-faced adhesive tape decreases when the semiconductor element generates heat. This causes the flexible wiring board mounted with the semiconductor element to be removed from the metal plate due to mechanical stress such as strain caused by mounting, leading to a broadened distance between the semiconductor element and the metal plate. This results in a thicker heat conductive component or causes the heat conductive component to be removed, leading to greater heat resistance and malfunction.

In view of the forgoing, a first object of the present invention is to provide an electronic device which prevents malfunction of the semiconductor element due to heat by increasing efficiency in dissipating heat.

Further, a second object of the present invention is to provide an electronic device capable of preventing malfunction of the semiconductor element due to heat by lowering heat resistance that depends on the thickness of the heat conductive component.

Furthermore, a third object of the present invention is to provide an electronic device capable of preventing malfunction of the semiconductor element due to mechanical reason.

An electronic device according to an implementation of the present invention includes: a heat sink including a front surface having a concave portion; a heat conductive component placed in the concave portion, the heat conductive component being in contact with the heat sink; a semiconductor element placed in the concave portion, the semiconductor element being in contact with the heat conductive component; a wiring component electrically connected to the semiconductor element and placed on the front surface of the heat sink; and a base plate having a surface on which the heat sink is fixed in contact with a back surface of the heat sink.

With the above configuration, the heat sink is fixed to the base plate such that the back surface of the heat sink opposite to the front surface where the concave portion is formed comes in contact with the base plate. Thus, the contact portion between the heat sink and the base plate is not subject to the limitation from the concave portion. Therefore, it is possible to reduce heat resistance in a route for dissipating heat in which heat from the semiconductor element is transmitted through the heat conductive component and the heat sink to the base plate, by enlarging the contact area between the heat sink and the base plate and bringing the contact portion between the heat sink and the base plate into close proximity with the located area of the semiconductor element. As a result, the heat from the semiconductor element is efficiently transmitted from the heat sink to the base plate through the heat conductive component, making it possible to prevent malfunction of the semiconductor element caused by heat.

An electronic device according to another implementation of the present invention includes: a first heat sink including a front surface having a concave portion; a heat conductive component placed in the concave portion, the heat conductive component being in contact with the first heat sink; a semiconductor element placed in the concave portion, the semiconductor element being in contact with the heat conductive component; a wiring component electrically connected to the semiconductor element and placed on the front surface of the first heat sink; a second heat sink placed on the front surface of the first heat sink, the second heat sink being in contact with the wiring component; and a base plate having a surface on which the first heat sink and the second heat sink are fixed.

With the above configuration, the semiconductor element is located in the concave portion of the first heat sink so as to be in contact with the heat conductive component, and the second heat sink is located on the front surface of the first heat sink on which the concave portion is formed. Therefore, as a principal route for dissipating heat, a route in which heat from the semiconductor element is transmitted through the second heat sink to the base plate is further provided. As a result, the heat from the semiconductor element is efficiently transmitted through the heat conductive component, the first heat sink, and the second heat sink to the base plate, and thus heat dissipation performance is enhanced, making it possible to prevent malfunction of the semiconductor element caused by heat.

In addition, the second heat sink causes the semiconductor element to be pressed to a heat dissipating component in the concave portion of the first heat sink, and thus the thickness of the heat conductive component can be made smaller and be stabilized, making it possible to further reduce heat resistance in the route for dissipating heat. As a result, it is possible to prevent malfunction of the semiconductor element caused by heat.

Further, the flexible wiring board is fixed on the base plate such that the flexible wiring board is placed between the first heat sink and the second heat sink. Thus, it is possible to prevent the flexible wiring board attached with a double-faced tape or the like from removing from the heat sink due to mechanical stress caused by strain at the time of mounting. Thus, it is possible to prevent malfunction of the semiconductor element due to mechanical reason.

An electronic device according to another implementation of the present invention includes: a heat sink; a base plate having a surface on which the heat sink is fixed; a semiconductor element placed between the heat sink and the base plate; a wiring component electrically connected to the semiconductor element and placed between the heat sink and the base plate; and a heat conductive component placed between the heat sink and the base plate and fixes the heat sink to the base plate, the heat conductive component being in contact with the heat sink and the semiconductor element.

With the above configuration, heat generated in the semiconductor element is transmitted through the heat conductive component directly to the base plate. As a result, since the heat of the semiconductor element is efficiently transmitted to the base plate, it is possible to prevent malfunction of the semiconductor element caused by heat.

According to the present invention, it is possible to obtain a configuration in which a route for dissipating heat from the semiconductor element is increased and heat conduction is stabilized, and a configuration in which contact between the semiconductor element and the heat dissipating component is maintained against mechanical stress, thereby preventing malfunction of the semiconductor element caused by heat and mechanical reason.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a perspective view which shows an example of a schematic configuration of an entire plasma display apparatus;

FIG. 2 is a block diagram which shows a configuration of a circuit block in the plasma display apparatus;

FIG. 3 is a sectional view of an electronic device viewed from a lateral side according to a first embodiment of the present invention;

FIG. 4 is a plan view of the electronic device viewed from the above according to the first embodiment;

FIG. 5 is a sectional view of a modification example of the electronic device viewed from a lateral side according to the first embodiment;

FIG. 6 is a plan view of a modification example of the electronic device viewed from the above according to the first embodiment;

FIG. 7A is a sectional view of a modification example of the electronic device viewed from a lateral side according to the first embodiment;

FIG. 7B is a sectional view of a modification example of the electronic device viewed from a lateral side according to the first embodiment;

FIG. 7C is a sectional view of a modification example of the electronic device viewed from a lateral side according to the first embodiment;

FIG. 8A is a sectional view of a modification example of the electronic device viewed from a lateral side according to the first embodiment;

FIG. 8B is a sectional view of a modification example of the electronic device viewed from a lateral side according to the first embodiment;

FIG. 8C is a sectional view of a modification example of the electronic device viewed from a lateral side according to the first embodiment;

FIG. 8D is a sectional view of a modification example of the electronic device viewed from a lateral side according to the first embodiment;

FIG. 8E is a sectional view of a modification example of the electronic device viewed from a lateral side according to the first embodiment;

FIG. 9 is a sectional view of an electronic device viewed from a lateral side according to a second embodiment of the present invention;

FIG. 10 is a plain view of the electronic device viewed from the above according to the second embodiment;

FIG. 11A is a sectional view of a modification example of the electronic device viewed from a lateral side according to the second embodiment;

FIG. 11B is a sectional view of a modification example of the electronic device viewed from a lateral side according to the second embodiment;

FIG. 11C is a sectional view of a modification example of the electronic device viewed from a lateral side according to the second embodiment;

FIG. 11D is a sectional view of a modification example of the electronic device viewed from a lateral side according to the second embodiment;

FIG. 11E is a sectional view of a modification example of the electronic device viewed from a lateral side according to the second embodiment;

FIG. 11F is a sectional view of a modification example of the electronic device viewed from a lateral side according to the second embodiment;

FIG. 11G is a sectional view of a modification example of the electronic device viewed from a lateral side according to the second embodiment;

FIG. 12A is a sectional view of a modification example of the electronic device viewed from a lateral side according to the second embodiment;

FIG. 12B is a sectional view of a modification example of the electronic device viewed from a lateral side according to the second embodiment;

FIG. 12C is a sectional view of a modification example of the electronic device viewed from a lateral side according to the second embodiment;

FIG. 13 is a sectional view of a modification example of an electronic device viewed from a lateral side according to the second embodiment;

FIG. 14A is a sectional view of a modification example of the electronic device viewed from a lateral side according to the second embodiment;

FIG. 14B is a sectional view of a modification example of the electronic device viewed from a lateral side according to the second embodiment;

FIG. 14C is a sectional view of a modification example of the electronic device viewed from a lateral side according to the second embodiment;

FIG. 15A is a sectional view of a modification example of the electronic device viewed from a lateral side according to the second embodiment;

FIG. 15B is a sectional view of a modification example of the electronic device viewed from a lateral side according to the second embodiment;

FIG. 15C is a sectional view of a modification example of the electronic device viewed from a lateral side according to the second embodiment;

FIG. 16 is a sectional view of a modification example of an electronic device viewed from a lateral side according to the second embodiment;

FIG. 17 is a sectional view of a conventional electronic device viewed from a lateral side; and

FIG. 18 is a plain view of the conventional electronic device viewed from the above.

### DESCRIPTION OF THE PREFERRED EMBODIMENTS

An electronic device according to an embodiment of the present invention will be described below with reference to the drawings.

### Embodiment 1

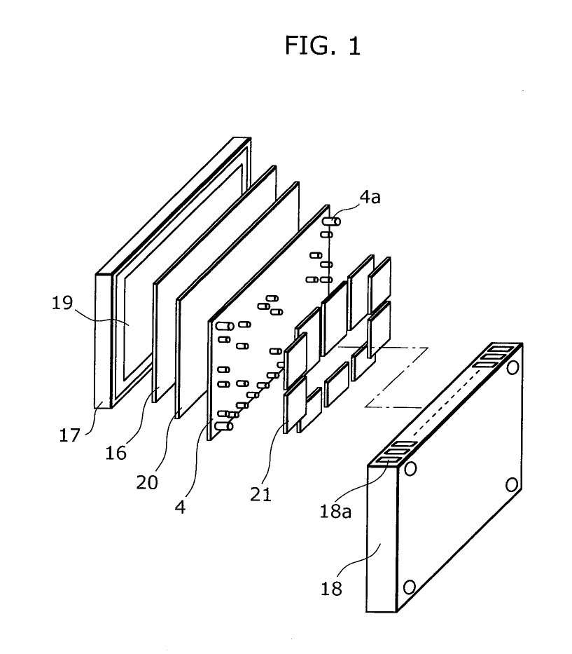

FIG. 1 is a perspective view which shows an example of a schematic configuration of an entire plasma display apparatus on which an electronic device is mounted.

The plasma display apparatus includes: a chassis member 4; a panel 16; a front frame 17 including a front cover 19; a back cover 18; a heat-conductive sheet 20; and a circuit block 21. The chassis member 4 is an example of a base plate according to an implementation of the present invention.

A housing in which the panel 16 is contained includes the front frame 17 and the back cover 18 made of metal. The front frame 17 includes an opening on which the front cover 19 made of glass or the like is arranged to serve also as a protector of an optical filter and the panel 16. Further, the back cover 18 includes plural vents 18a for dissipating heat generated in the panel 16 and the like outside.

The panel 16 is bonded to the front surface of the chassis member 4 made of an aluminum flat plate with the heat-conductive sheet 20 sandwiched in between, thereby being held by the chassis member 4. The plural circuit blocks 21 for driving the panel 16 to display are attached on the back surface of the chassis member 4.

The heat-conductive sheet 20 efficiently transfers the heat generated in the panel 16 to the chassis member 4 for dissipation. Further, each of the circuit blocks 21 includes an electric circuit for driving the panel 16 to display and controlling the driving, and is electrically connected to an electrode extracting unit extracted to an edge of the panel 16 by plural flexible wiring boards (not illustrated) that extends over the edges of four sides of the chassis member 4.

The chassis member 4 includes, on the back surface (front surface), plural boss portions 4a for mounting the circuit blocks 21 or fixing the back cover 18. The boss portions 4a are configured of a fixed pin fixed to the aluminum flat plate.

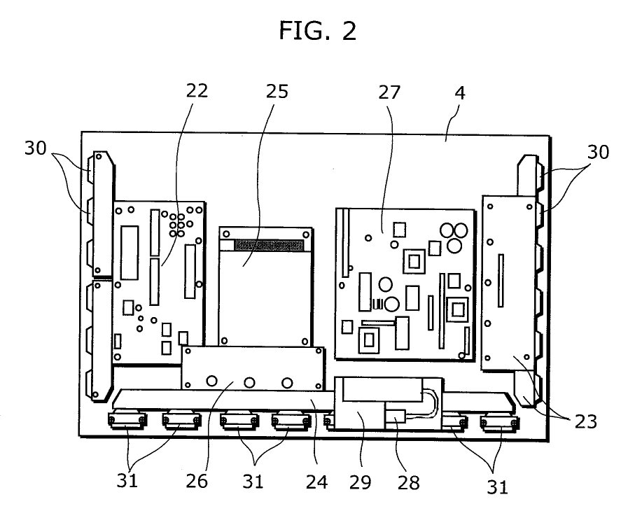

FIG. 2 is a block diagram which shows a configuration of each of the circuit blocks 21 in the plasma display apparatus according to the above configuration.

The circuit block 21 includes: a scan driver circuit block 22; a sustain driver circuit block 23; an address driver circuit block 24; a control circuit block 25; an input signal circuit block 26; a power source block 27; a power input block 29 having a connector 28; and flexible wiring boards 30 and 31.

The scan driver circuit block 22 applies a predetermined signal voltage to a scan electrode of the panel 16. The sustain driver circuit block 23 applies a predetermined signal voltage to a sustain electrode of the panel 16. The address driver circuit block 24 applies a predetermined signal voltage to an address electrode of the panel 16 and supplies display data to the address electrode. The scan driver circuit block 22 and the sustain driver circuit block 23 are placed at the ends of the chassis member 4, respectively, in a scan width direction (in the width direction of the chassis member 4), and the address driver circuit block 24 is placed at the bottom end of the chassis member 4.

The control circuit block 25 converts image data, based on an image signal transmitted from the inputted signal circuit block 26, into an image data signal that corresponds to the number of pixels of the panel 16 and supplies the image data signal to the address driver circuit block 24. Further, the control circuit block 25 generates a discharge control timing signal and supplies the discharge control timing signal to the scan driver circuit block 22 and the sustain driver circuit block 23, thereby controlling driving for display, such as gray level control. The control circuit block 25 is placed approximately at the center of the chassis member 4.

The input signal circuit block 26 includes an input terminal to which a connecting cable for interfacing to an external device such as a TV tuner is removably connected.

The power source block 27 applies a voltage to each of the circuit blocks, is placed approximately at the center of the chassis member 4 as with the control circuit block 25, and is provided with commercial power supply and voltage through the power input block 29 to which a power supply cable (not illustrated) is attached.

The flexible wiring board 30 connects the scan electrode of the panel 16 and the electrode extracting unit of the sustain electrode to a printed-wiring board of the scan driver circuit block 22 and the sustain driver circuit block 23.

The flexible wiring board 31 is an example of the wiring component according to an implementation of the present invention, and connects the electrode extracting unit of the address electrode of the panel 16 and a printed board mounted with a driving circuit of the address driver circuit (address driver circuit block 24). Each of the flexible wiring boards 30 and 31 is placed to extend from the front side to the rear side with a bend of 180 degrees through a periphery of the panel 16.

The electronic device according to an implementation of the present invention includes: the address driver circuit block 24; the flexible wiring board 31; and the chassis member 4.

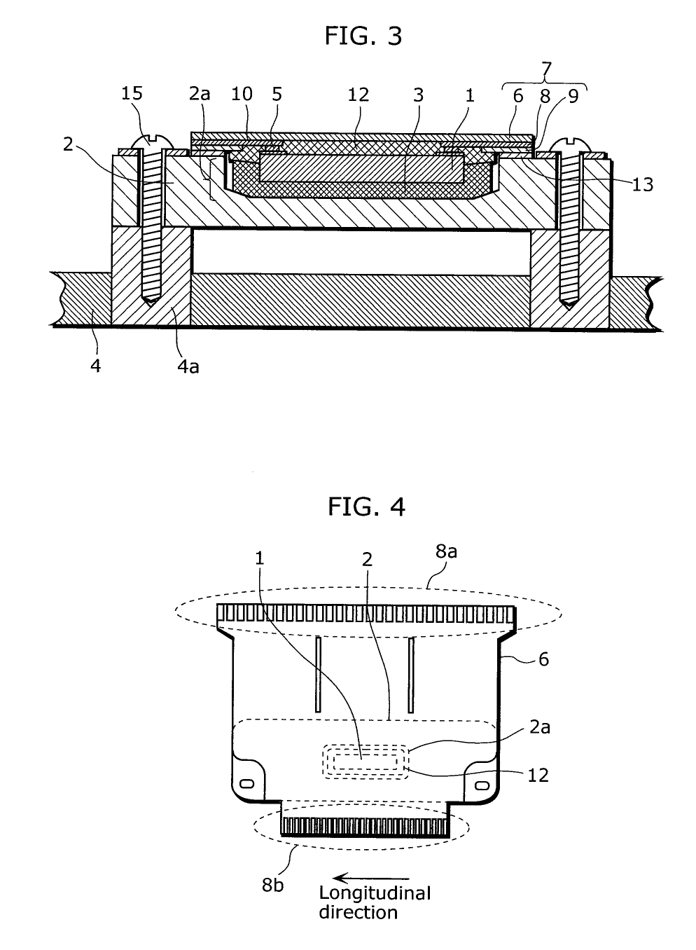

FIG. 3 is a sectional view of the electronic device viewed from a lateral side according to the present embodiment. FIG. 4 is a plan view of the same electronic device viewed from the above.

The electronic device includes: a semiconductor element 1 that composes an address driver circuit block 24; a heat sink 2; a heat conductive component 3; a resin 12; a double-faced adhesive tape 13; screws 15; a chip on film (COF) tape as an example of the flexible wiring board 31; and the chassis member 4.

The heat sink 2, the semiconductor element 1; and the opening of the concave portion 2a of the heat sink 2 have a rectangle shape when viewed from the front side of the heat sink 2, as shown in FIG. 4. The concave portion 2a is formed such that the longitudinal side of the rectangular opening is parallel to the longitudinal side of the rectangular heat sink 2. The semiconductor element 1 is placed such that the longitudinal side of the rectangular semiconductor element 1 is parallel to the longitudinal side of the rectangular opening of the concave portion 2a.

The COF tape is formed of a flexible base plate 7 and includes a portion which is connected to a protruding electrode 5 of the semiconductor element and which is not opened, as shown in FIG. 3 and FIG. 4. The COF tape is electrically connected to the semiconductor element 1 and place on the surface of the heat sink 2. The heat sink 2 is fixed to the front surface of the chassis member 4 in such a manner as being in contact with the entire back surface (back surface facing the base plate) opposite to the front surface of the heat sink 2.

The flexible base plate 7 includes: a base film 6 formed of a polyimide film or the like that has high flexibility; conducting wires 8 formed of copper foil or the like on the base film 6; and a solder resist 9 formed of a polyimide or the like that covers the surface of the conducting wires 8 to protect the conducting wires 8. Each of the conducting wires 8 has a first terminal connected to the electrode extracting unit of the address electrode of the panel 16 via an anisotropic conductive film or the like, and a second terminal connected to the semiconductor element 1. The conducting wire 8 (an inner lead 10) of the flexible base plate 7 protrudes to the opening of the concave portion 2a. The protruding electrode 5 of the semiconductor element 1 is electrically connected to the protrusion of the conducting wire 8.

The conducting wire 8 includes: the inner lead 10; and the terminal 8a connected to the electrode extracting unit of the address electrode and the terminal 8b connected to the driving circuit board, each of which is exposed to the surface, as shown if FIG. 4. In addition, the exposed terminals 8a and 8b are plated with the Sn, Au, or the like.

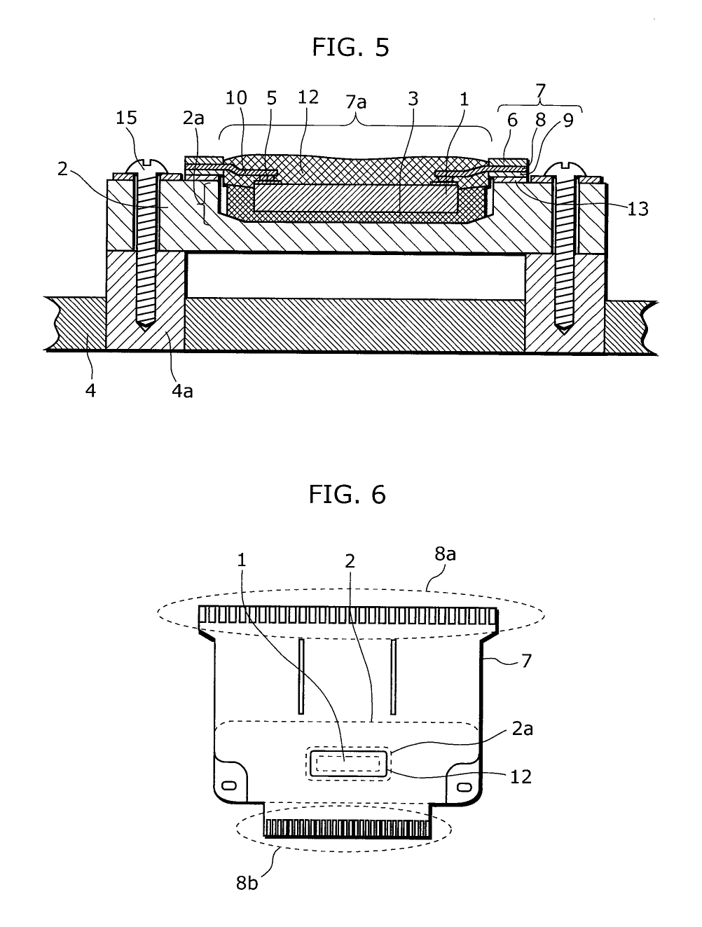

Although the COF tape is illustrated as an example of the flexible wiring board 31, the flexible wiring board 31 may be a tape automated bonding (TAB) as shown in the sectional view of FIG. 5 and the plan view of FIG. 6. In this case, the inner lead 10 connected to the protruding electrode 5 of the semiconductor element 1 is formed to protrude from the opening 7a of the flexible base plate 7 (base film 6). However, the address driver circuit block 24 may be formed to have the same configuration. Further, the flexible wiring board 31 may be a tape carrier package (TCP).

The semiconductor element 1 is an element for supplying display data to the address electrode of the panel 16. The semiconductor element 1 includes the protruding electrode 5 made from Au or the like to serve as an input and output terminal. The protruding electrode 5 is eutectically bonded to the exposed inner lead 10 of the COF tape, so that the semiconductor element 1 is electrically connect to the COF tape.

The heat sink 2 includes an area in which the semiconductor element 1 is placed (in the concave portion 2a) and which is filled with the resin 12 such as an epoxy resin so as to fix the semiconductor element 1 in the concave portion 2a and to coat a portion in which the protruding electrode 5 of the semiconductor element 1 and the inner lead 10 of the COF tape come in contact with each other, and the semiconductor element 1 and a junction area are protected from mechanical stress.

The heat sink 2 is made of a metal plate, for example an aluminum plate or the like on which the semiconductor element 1 is mounted. The concave portion 2a in which the semiconductor element 1 is placed is formed on the surface of the heat sink 2. In the concave portion 2a, the semiconductor element 1 is placed in such a manner as being in contact with the heat conductive component 3, and the heat conductive component 3 such as heat conductive grease or heat conductive adhesive is placed and filled in such a manner as being the heat sink 2. The heat sink 2 is bonded to the COF tape by using heat resistant double-faced adhesive tape 13 or the like.

The heat sink 2 includes threaded holes that penetrate therethrough around the concave portion 2a (both ends), and the surface of the chassis member 4 includes threaded holes on positions corresponding to the threaded holes of the heat sink 2. The heat sink 2 is fixed to the chassis member 4 by threading each of the screws 15 through a corresponding one of the threaded holes of the heat sink 2 and the chassis member 4, in a manner so that the back surface of the heat sink 2 which is the opposite side to the front surface of the heat sink 2 on which the concave portion 2a is formed, that is, the front surface that is bonded to the COF tape, comes in contact with the boss portion (convex portion) 4a in which a threaded hole is formed. In other words, the heat sink 2 is fixed to the chassis member 4 with the screws 15.

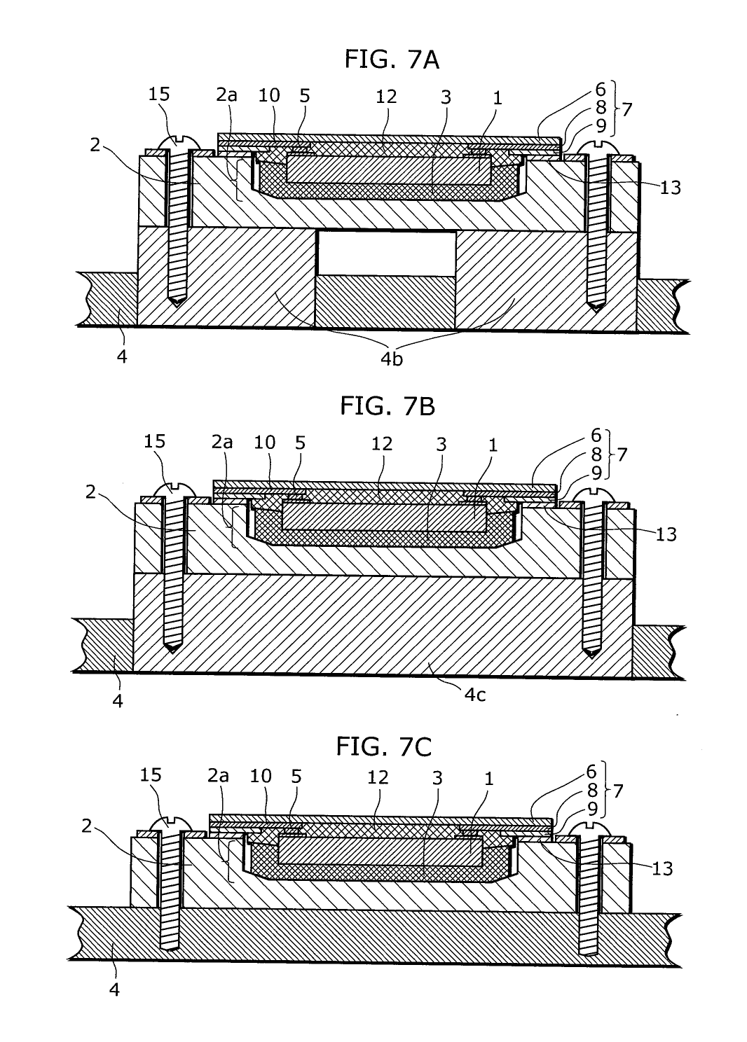

Since the COF tape is bonded to the face that comes in contact with the boss portion 4a of the heat sink 2 according to the conventional electronic devices, the contact area of the boss portion 4a and the heat sink 2 is limited and cannot be enlarged. In the electronic device according to the present embodiment, however, since the COF tape is not bonded to the face that comes in contact with the boss portion of the heat sink 2, it is possible to enlarge a cross-sectional area of the boss portions 4b each of which includes a threaded hole as shown in the sectional view of the electronic device in FIG. 7A, allowing the boss portions 4b to be also formed in the area under the semiconductor element 1 that is the heat source. This makes it possible to transfer the heat highly-efficiently from the semiconductor element 1 to the chassis member 4. In addition, it is also possible to integrated the two boss portions 4a to form a new boss portion 4c which includes threaded holes, so that the entire top surface of the boss portion 4c comes in contact with the heat sink 2, as shown in the sectional view of the electronic device of FIG. 7B. This makes it possible to shorten the route for dissipating heat from the semiconductor element 1 to the chassis member 4.

Further, in the electronic device according to the above embodiment, the heat sink 2 is fixed to the chassis member 4 using the boss portion 4a. However, the boss portion 4a may be removed and the heat sink 2 may directly come in contact with the chassis member 4 on the back surface that is the opposite side to the front surface bonded to the COF tape without using the boss portion 4a and be fixed to the chassis member 4 with the screw 15, as shown in the sectional view of the electronic device in FIG. 7C. In this case, it is possible to transfer the heat highly-efficiently from the semiconductor element 1 to the chassis member 4 and to further shorten the route for dissipating heat from the semiconductor element 1 to the chassis member 4.

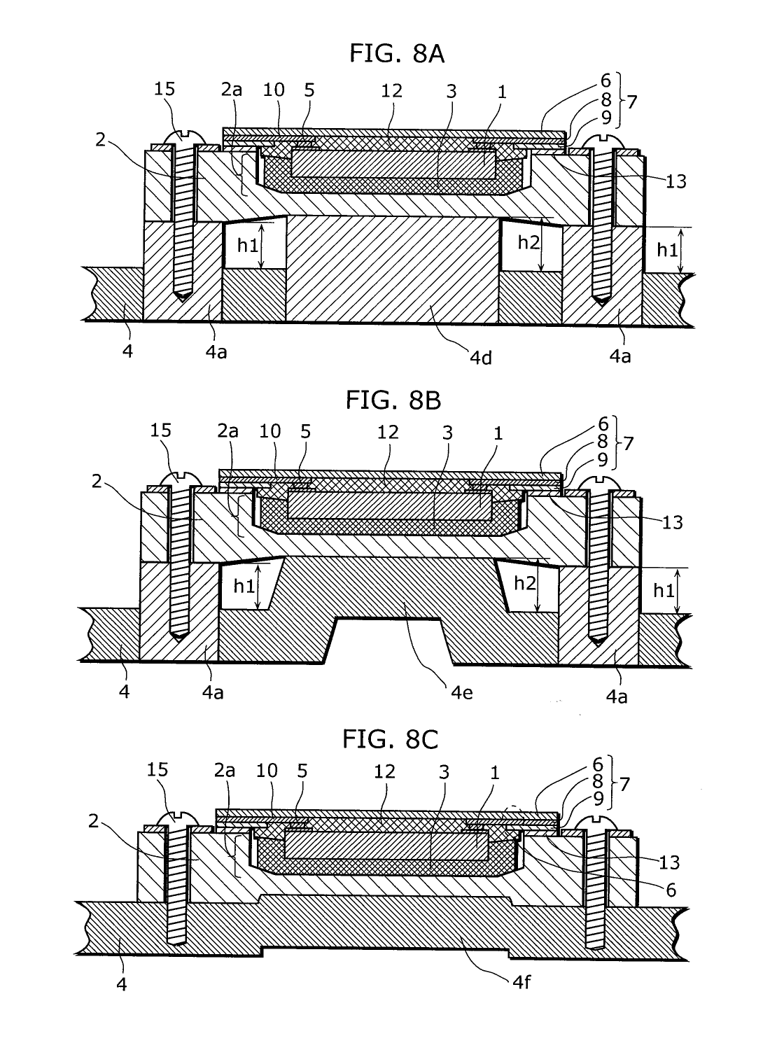

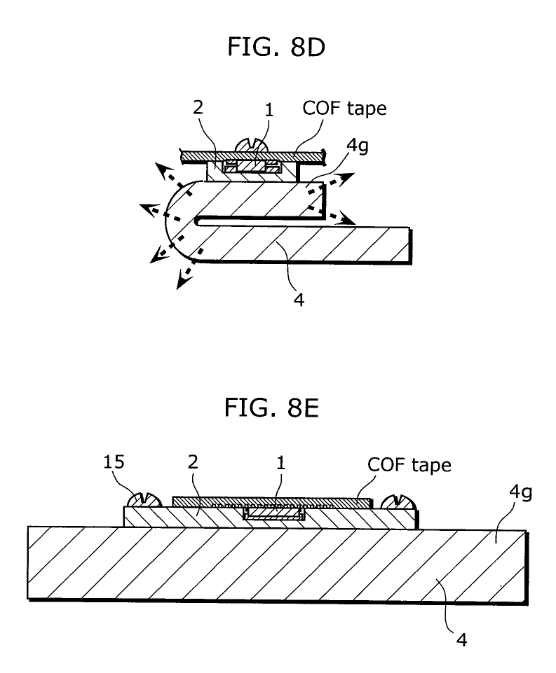

Further, as shown in the sectional view of the electronic device in FIG. 8A, the electronic device may include an independent protrusion that protrudes to the heat sink 2 as a boss portion 4d in the area under the semiconductor element 1 between the two boss portions 4a so that the boss portion 4d is positioned at the center between the two boss portions 4a. In this case, a height h2 of the boss portion 4d is greater than a height h1 of the boss portions 4a, that is, h1<h2, allowing the boss portion 4d that is close to the heat source to come securely in contact with the heat sink 2, so that the heat dissipation structure is stabilized. This also makes it possible to transfer the heat highly-efficiently from the semiconductor element 1 to the chassis member 4.

Furthermore, as shown in the sectional view of the electronic device in FIG. 8B, the chassis member 4 may be formed so that a protrusion 4e of the chassis member 4 is formed at the center between the two boss portions 4a in the area under the semiconductor element 1, in other words, a transformed portion that is deflected convexly toward the heat sink 2 is formed in the chassis member 4. In this case, the height h2 of the transformed portion of the chassis member 4 from the front surface of the chassis member 4 is greater than the height h1 of the boss portions 4a from the front surface of the chassis member 4, and the heat sink 2 is fixed to the chassis member 4 in a manner so that the transformed portion of the chassis member 4 comes in contact with the back surface of the heat sink 2. Furthermore, as shown in the sectional view of the electronic device in FIG. 8C, the chassis member 4 may be formed so that the heat sink 2 is directly fixed to the chassis member 4 without using the boss portion 4a, and a protrusion 4f of the chassis member 4 is positioned in the area under the semiconductor element 1, in other words, a transformed portion that is deflected convexly toward the heat sink 2 is formed in the chassis member 4. Furthermore, as shown in the sectional views of the electronic devices in FIG. 8D and FIG. 8E, the chassis member 4 may be formed so that the heat sink 2 is directly fixed to the chassis member 4 without using the boss portion 4a, and that a bent portion 4g of the chassis member 4 may be positioned in the area under the semiconductor element 1, in other words, the chassis member 4 may include an edge bent into a horseshoe shape on which the heat sink 2 and the COF tape are placed. In this case, the heat sink 2 is fixed to the chassis member 4 in a manner so that the transformed portion or the bent portion of the chassis member 4 comes in contact with the back surface of the heat sink 2. This makes it possible to enhance heat dissipation performance without increasing the number of components which would lead increase of costs. This also makes it possible to transfer the heat highly-efficiently from the semiconductor element 1 to the chassis member 4 and to further shorten the route for dissipating heat from the semiconductor element 1 to the chassis member 4.

As described above, the electronic device according to the present embodiment, heat from the semiconductor element 1 is efficiently transferred from the heat sink 2 to the chassis member 4 via the heat conductive component 3. As a result, it is possible to prevent malfunction of the semiconductor element caused by heat.

### Embodiment 2

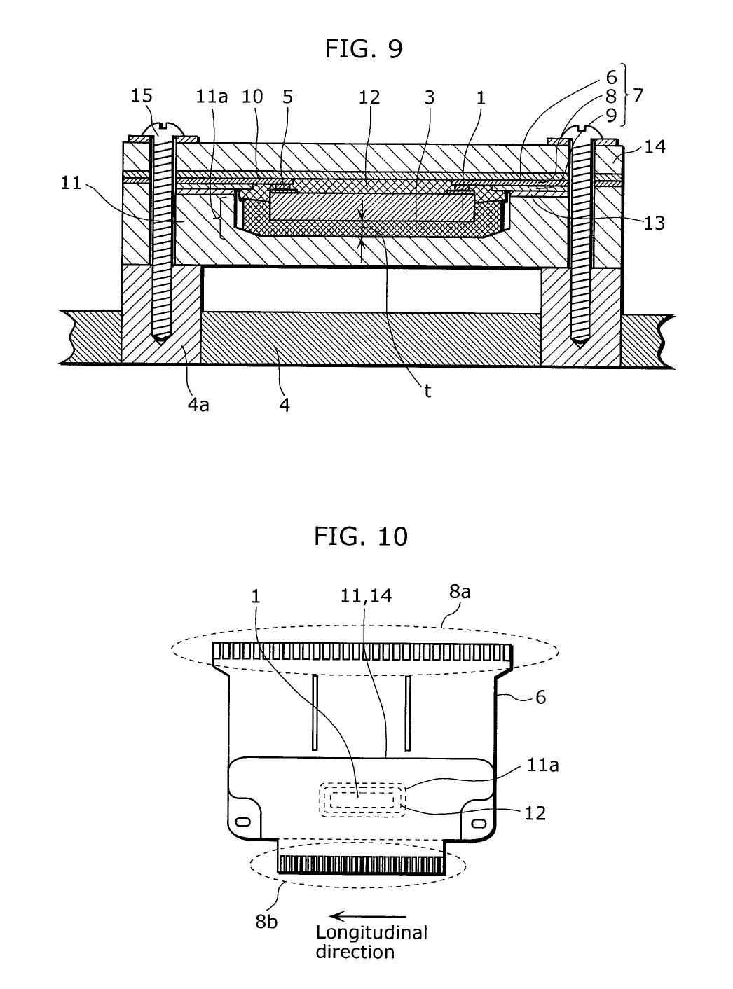

FIG. 9 is a sectional view of an electronic device viewed from a lateral side according to the present embodiment. FIG. 10 is a plan view of the electronic device viewed from the above. It is to be noted that, in FIG. 9 and FIG. 10, the same numerals are assigned to the same elements as in FIG. 3 and FIG. 4 and detailed description for those elements will be omitted.

The electronic device includes: a semiconductor element 1 that composes an address driver circuit block 24; a heat conductive component 3; a resin 12; a double-faced adhesive tape 13; a first heat sink 11; a second heat sink 14; screws 15; a COF tape as an example of the flexible wiring board 31; and a chassis member 4.

The first heat sink 11, the second heat sink 14, the semiconductor element 1, and an opening of the concave portion 11a of the first heat sink 11 have a rectangle shape when viewed from the front side of the first heat sink 11, as shown in FIG. 10. The concave portion 11a is formed such that the longitudinal side of the rectangular opening is parallel to the longitudinal side of the rectangular heat sink 11. The second heat sink 14 and the semiconductor element 1 is placed such that the longitudinal side of the rectangular semiconductor element 1 and the longitudinal side of the rectangular second heat sink 14 are parallel to the longitudinal side of the rectangular opening of the concave portion 11a. Further, the external dimensions of the second heat sink 14 are larger than the external dimensions of the semiconductor element 1.

The first heat sink 11 includes an area in which the semiconductor element 1 is placed (in the concave portion 11a) and which is filled with the resin 12 so as to fix the semiconductor element 1 in the concave portion 11a and to coat a portion in which the protruding electrode 5 of the semiconductor element 1 and the inner lead 10 of the COF tape come in contact with each other, and the semiconductor element 1 and a junction area are protected from mechanical stress.

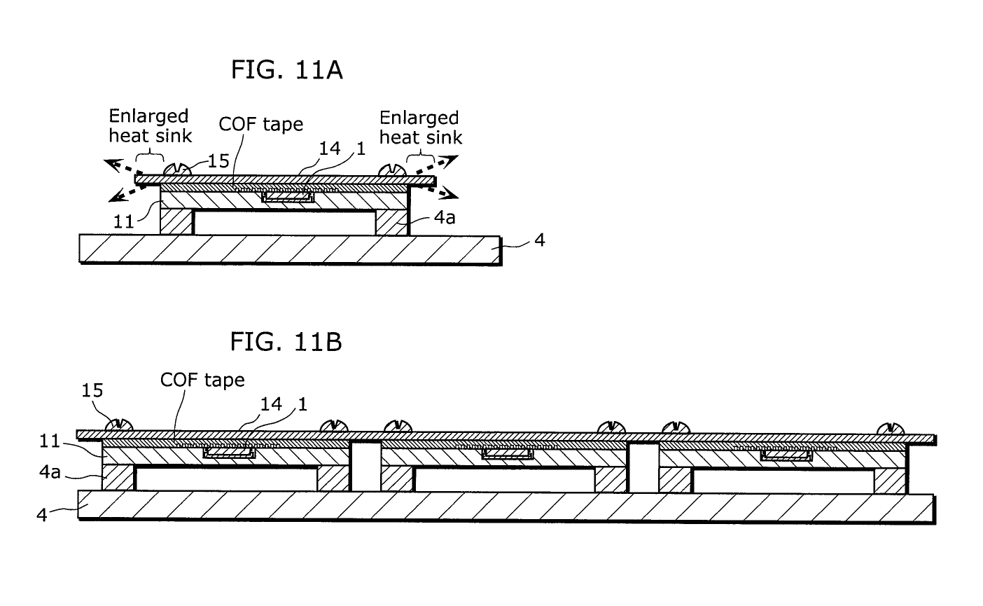

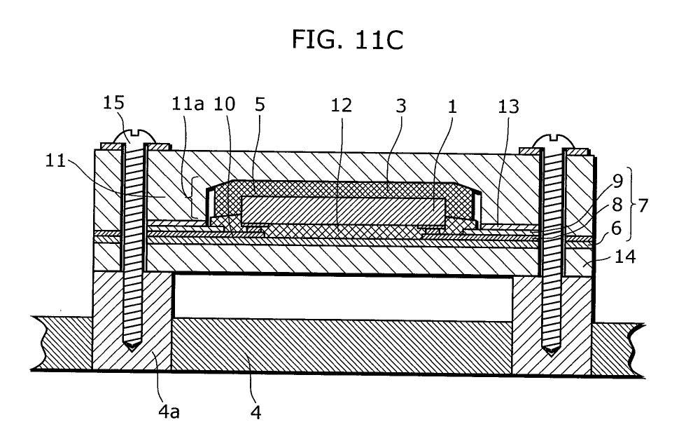

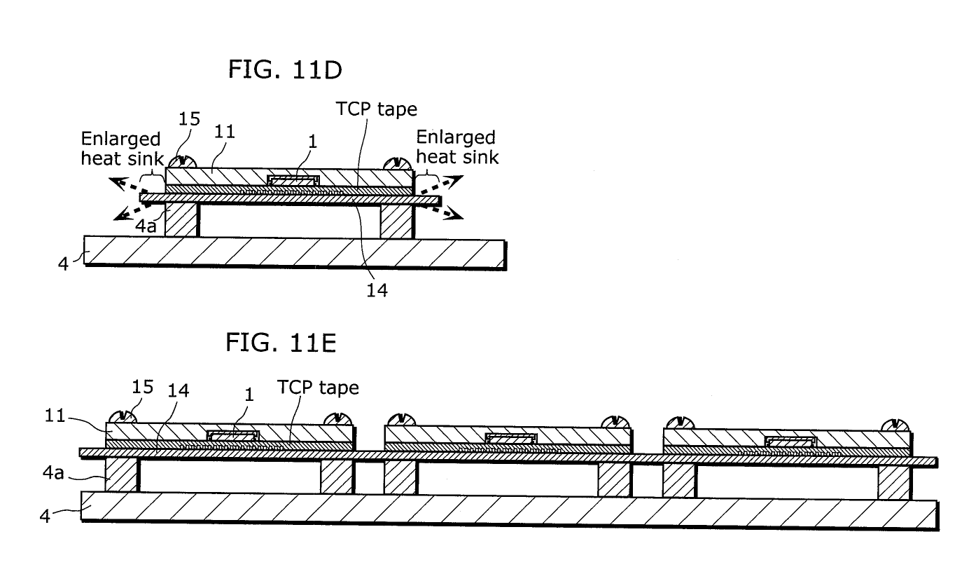

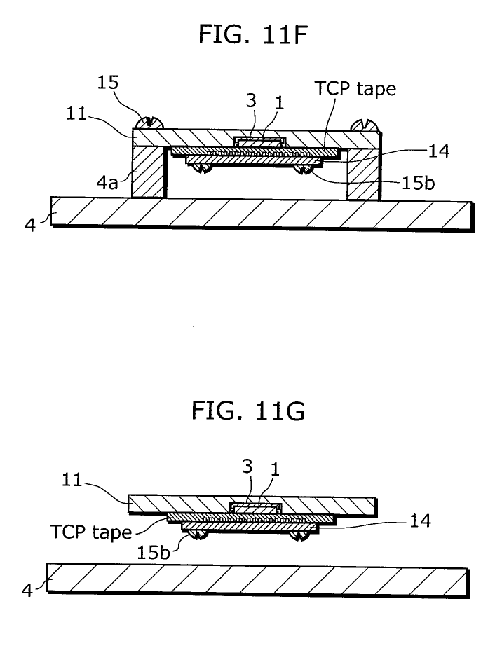

The first heat sink 11 is made of a metal plate, for example an aluminum plate or the like on which the semiconductor element 1 is mounted. The concave portion 11a in which the semiconductor element 1 is placed is formed on the front surface of the first heat sink 11. In the concave portion 11a, the semiconductor element 1 is placed in a manner as being in contact with the heat conductive component 3, and the heat conductive component 3 is placed and filled in a manner as being in contact with the first heat sink 11. The first heat sink 11 is bonded to the COF tape by using a heat resistant double-faced adhesive tape 13 or the like. The surface of the second heat sink 14 facing the surface of the first heat sink 11 is placed on the surface of the first heat sink 11 on top of the COF tape so as to come in contact with the area of the COF tape above the semiconductor element 1, and the second heat sink 14 nips the COF tape together with the first heat sink 11. It is to be noted that, as shown in FIG. 11A, external dimensions of the second heat sink 14 is larger than the external dimensions of the first heat sink 11 and the COF tape, and the edge of the second heat sink 14 may protrude from the edges of the first heat sink 11 and the COF tape. This makes it possible to dissipate the heat highly-efficiently from the semiconductor element 1 into the air.

Further, in the case where the electronic device includes plural first heat sinks 11 and plural COF tapes corresponding to the plural first heat sinks 11, a single second heat sink 14 may be provided above the plural first heat sinks 11 and plural COF tapes to be shared by the plural first heat sinks 11 and plural COF tapes, as shown in FIG. 11B. This makes it possible to dissipate the heat highly-efficiently from the semiconductor element 1 into the air, and to simplify the manufacturing process.

The first heat sink 11 includes threaded holes that penetrate therethrough around the concave portion 2a (both ends), and the second heat sink 14 includes threaded holes that penetrate therethrough on positions corresponding to the threaded holes of the first heat sink 11. Further, the surface of the chassis member 4 includes threaded holes on positions corresponding to the threaded holes of the first heat sink 11 and the second heat sink 14. The first heat sink 11 and the second heat sink 14 are fixed to the chassis member 4 by threading each of the screws 15 through a corresponding one of the threaded holes of the first heat sink 11, the second heat sink 14, and the chassis member 4, in a manner so that the back surface of the first heat sink 11 which is the opposite side to the front surface of the first heat sink 11 on which the concave portion 2a is formed, that is, the surface that bonded to the COF tape, comes in contact with the boss portion 4a. In other words, the first heat sink 11, the second heat sink 14, and the chassis member 4 are fixed together with the screws 15. It is to be noted that the first heat sink 11 and the second heat sink 14 may be fixed to the chassis member 4 in a reversed state with respect to the state of FIG. 9. as shown in the sectional view of the electronic device of FIG. 11C. More specifically, the first heat sink 11 and the second heat sink 14 may be fixed with screw such that the front surface of the second heat sink 14 which is the opposite side to the back surface facing the first heat sink 11 comes in contact with the boss section 4a of the chassis member 4. In this case, as shown in FIG. 11D, external dimensions of the second heat sink 14 is larger than the external dimensions of the first heat sink 11 and the TCP tape, and the edge of the second heat sink 14 may protrude from the edges of the first heat sink 11 and the COF tape. This makes it possible to dissipate the heat highly-efficiently from the semiconductor element 1 into the air. Further, in the case where the electronic device includes plural first heat sinks 11 and plural TCP tapes corresponding to the plural first heat sinks 11, a single second heat sink 14 may be provided under the plural first heat sinks and TCP tapes to be shared by the plural first heat sinks and TCP tapes, as shown in FIG. 11E. This makes it possible to dissipate the heat highly-efficiently from the semiconductor element 1 into the air, and to simplify the manufacturing process. Further, the second heat sink 14 may be fixed to the first heat sink 11 with a screw 15b that is different from the screw 15 that fixes the first heat sink 11 to the chassis member 4, as shown in FIG. 11F. In this case, the first heat sink 11 and the second heat sink 14 may be kept from coming in contact with the chassis member 4, as shown in FIG. 11G.

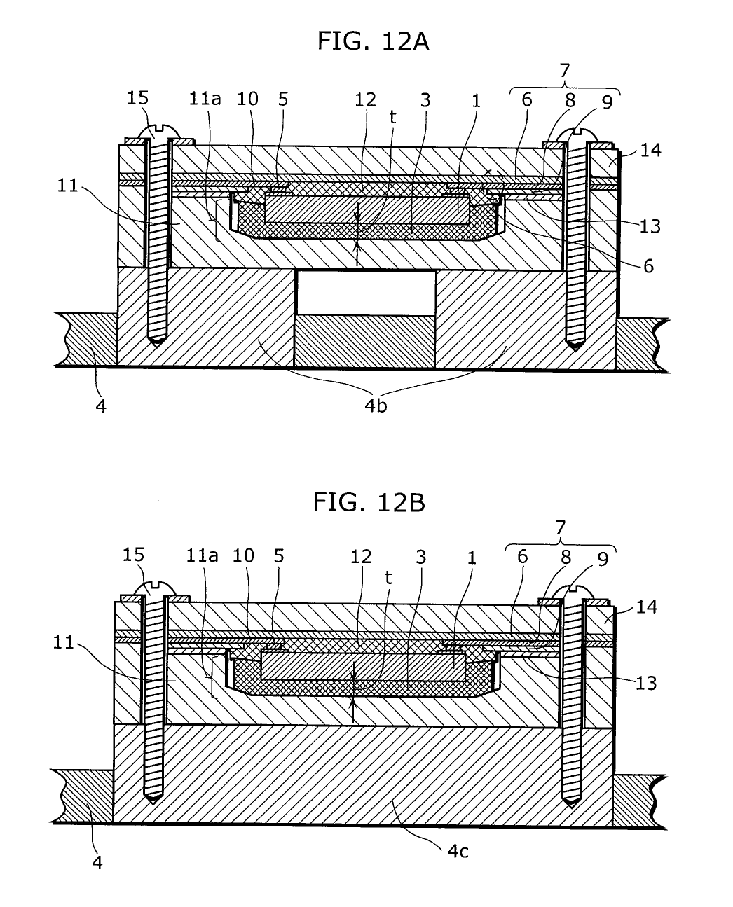

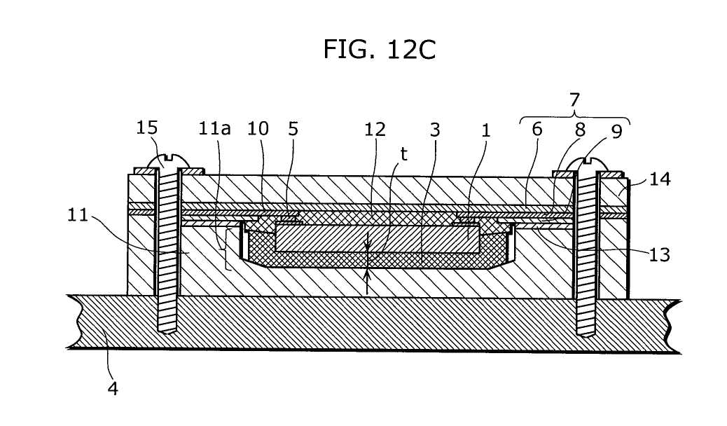

In conventional electronic devices, the COF tape is bonded to a face of the first heat sink 11 which comes in contact with the boss portion 4a, so that the contact area between the boss portion 4a and the first heat sink 11 is limited and cannot be enlarged. In the electronic device according to the present embodiment, however, the COF tape is not bonded to a face of the first heat sink 11 which comes in contact with the boss portion 4a, so that it is possible to enlarge the cross-sectional area of the boss portion 4b and to form the boss portion 4b also in the area under the semiconductor element 1 that is the heat source, as shown in the sectional view of the electronic device of FIG. 12A. This makes it possible to transfer the heat highly-efficiently from the semiconductor element 1 to the chassis member 4. In addition, it is also possible to integrate the two boss portions 4a to form a new boss portion 4c, so that the entire top surface of the boss portion 4c comes in contact with the first heat sink 11, as shown in the sectional view of the electronic device of FIG. 12B. This makes it possible to further shorten the route for dissipating heat from the semiconductor element 1 to the chassis member 4.

Further, in the electronic device according to the above-described embodiment, the first heat sink 11 is fixed to the chassis member 4 using the boss portion 4a sandwiched. However, the boss portion 4a may be removed, and the first heat sink 11 may be fixed to the chassis member 4 with the screw 15 such that the back surface of the first heat sink 11 which is the opposite side to the front surface that bonded to the COF tape comes in contact with the chassis member 4 without using the boss portion 4a, as shown in the sectional view of the electronic device of FIG. 12C. In this case, it is possible to transfer the heat highly-efficiently from the semiconductor element 1 to the chassis member 4 and to further shorten the route for dissipating heat from the semiconductor element 1 to the chassis member 4.

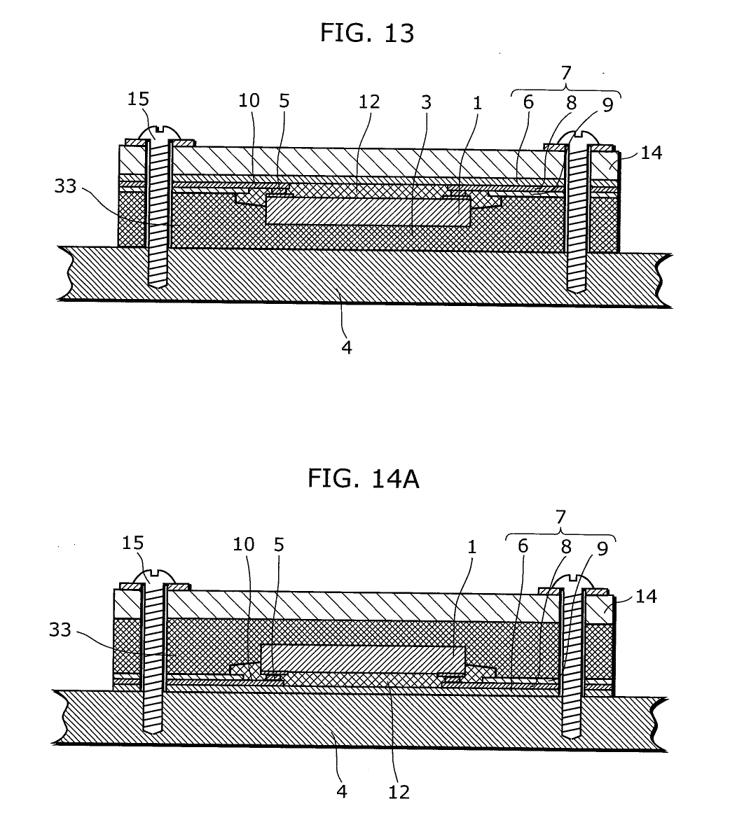

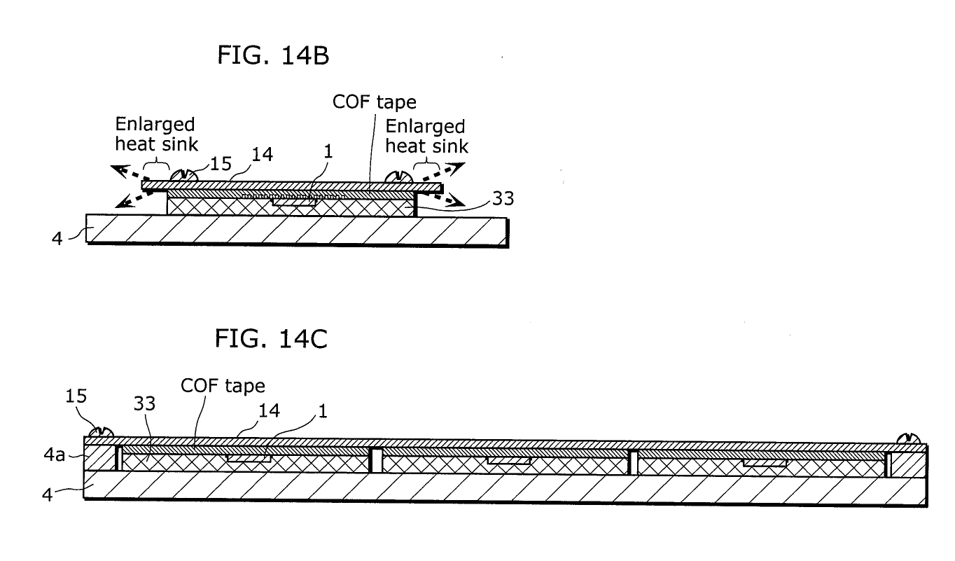

Further, in the electronic device according to the above-described embodiment, the second heat sink 14 is fixed to the chassis member 4 with the first heat sink 11 sandwiched between the second heat sink 14 and the chassis member 4, and the semiconductor element 1 is provided in the concave portion 2a of the first heat sink 11. However, the second heat sink 14 may be directly fixed to the chassis member 4 using a flexible heat-conductive sheet 33, as shown in the sectional view of the electronic device of FIG. 13. This enables reduction of the number of components and lowering costs. It is to be noted that the COF tape may be placed on the chassis member 4 instead of the second heat sink 14 by causing the flexible base plate 7 (base film 6) to adhere to the front surface of the chassis member 4, as shown in the sectional view of the electronic device of FIG. 14A. In addition, as shown in FIG. 14B, external dimensions of the second heat sink 14 is larger than the external dimensions of the COF tape, and the edge of the second heat sink 14 may protrude from the edges of the COF tape. This makes it possible to dissipate the heat highly-efficiently from the semiconductor element 1 into the air. Further, in the case where the electronic device includes plural COF tapes, a single second heat sink 14 may be provided above the plural COF tapes to be shared by the plural COF tapes, as shown in FIG. 14C. This makes it possible to dissipate the heat highly-efficiently from the semiconductor element 1 into the air, and to simplify the manufacturing process.

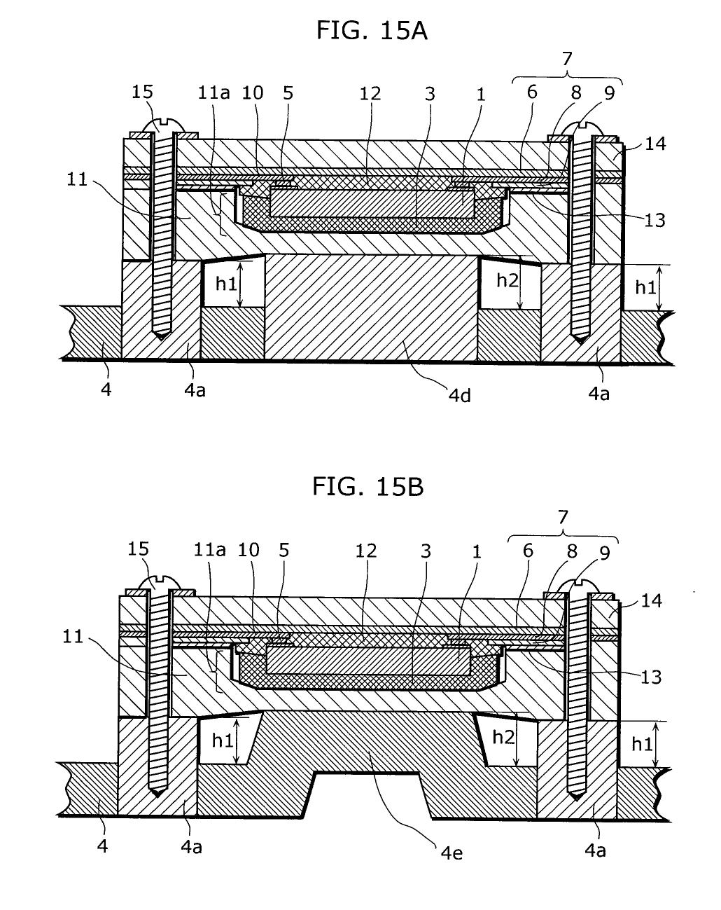

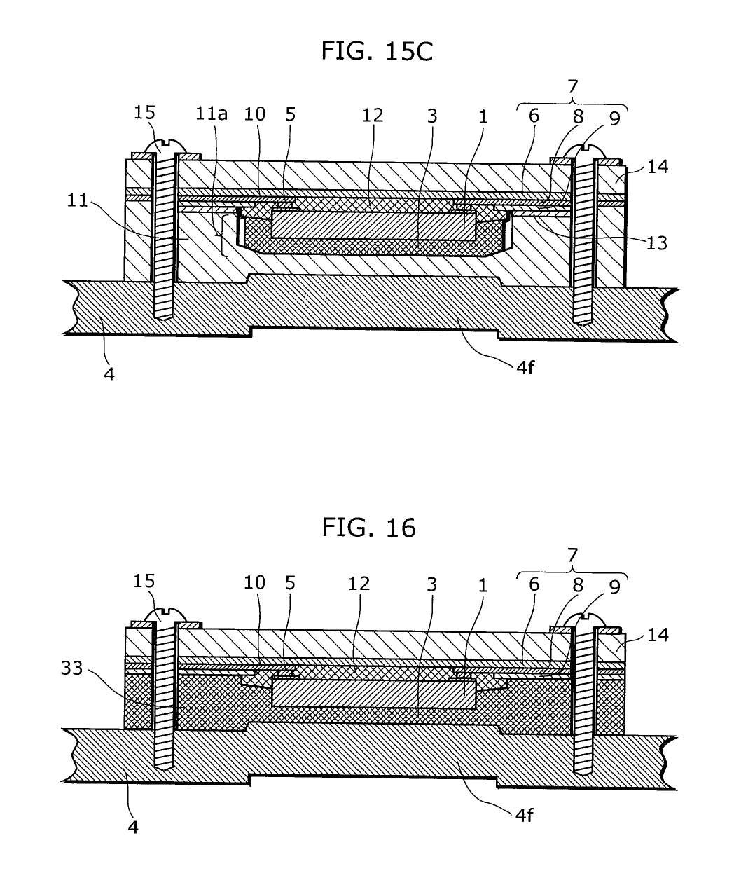

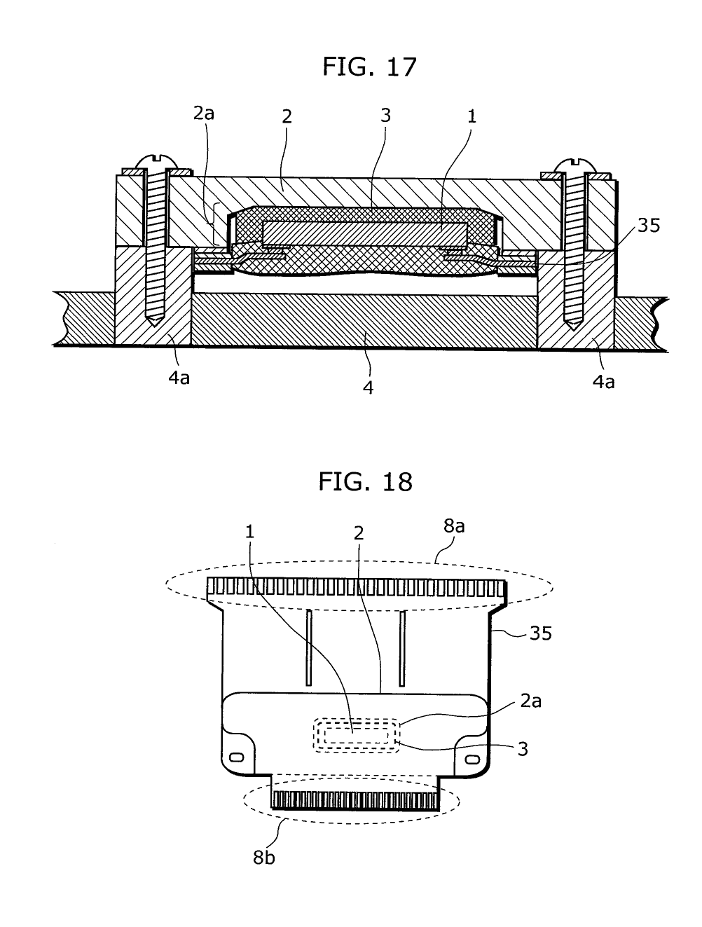

Further, as shown in the sectional view of the electronic device in FIG. 15A, the electronic device may include an independent protrusion as a boss portion 4b in the area under the semiconductor element 1 between the two boss portions 4a so that the boss portion 4b is positioned at the center between the two boss portions 4a. In this case, the height h2 of the boss portion 4d is greater than the height h1 of the boss portions 4a, that is, h1<h2, allowing the boss portion 4d that is close to the heat source to come securely in contact with the heat sink 11, so that the heat dissipation structure is stabilized. This also makes it possible to transfer the heat highly-efficiently from the semiconductor element 1 to the chassis member 4.

Furthermore, as shown in the sectional view of the electronic device in FIG. 15B, the chassis member 4 may be formed so that a protrusion 4e of the chassis member 4 is positioned at the center between the two boss portions 4a in the area under the semiconductor element 1 between the two boss portions 4a, in other words, a transformed portion that is deflected convexly toward the first heat sink 11 and the second heat sink 14 is included. In this case, the height h2 of the transformed portion of the chassis member 4 from the front surface of the chassis member 4 is greater than the height h1 of the boss portions 4a from the front surface of the chassis member 4, and the first heat sink 11 and the second heat sink 14 are fixed to the chassis member 4 in a manner so that the transformed portion of the chassis member 4 comes in contact with the back surface of the first heat sink 11.

Further, when fixed to the chassis member 4 in a reversed state with respect to the stated of FIG. 15B, the first heat sink 11 and the second heat sink 14 are fixed to the chassis member 4 in a manner so that the transformed portion of the chassis member 4 comes in contact with the front surface of the second heat sink 14. Or, the chassis member 4 may be formed so that the first heat sink 11 may be directly fixed to the chassis member 4 without using the boss portion 4a, and that a protrusion 4f of the chassis member 4 is formed in the area under the semiconductor element 1, in other words, a transformed portion that is deflected convexly toward the second heat sink 14 is formed in the chassis member 4, as shown in the sectional view of the electronic device in FIG. 15C. This makes it possible to enhance heat dissipation performance without increasing the number of components which leads to increased costs. This also makes it possible to transfer the heat highly-efficiently from the semiconductor element 1 to the chassis member 4 and to further shorten the route for dissipating heat from the semiconductor element 1 to the chassis member 4.

Further, the chassis member 4 may be formed so that the second heat sink 14 is directly fixed to the chassis member 4 using the heat-conductive sheet 33, and that a protrusion 4f of the chassis member 4 is formed in the area under the semiconductor element 1, in other words, a transformed portion that is deflected convexly toward the second heat sink 14 is include in the chassis member 4, as shown in the sectional view of the electronic device in FIG. 16. The electronic device shown in FIG. 16 includes: the second heat sink 14; the chassis member 4 having a surface to which the second heat sink 14 is fixed; the semiconductor element 1 placed between the second heat sink 14 and the chassis member 4; the flexible base plate 7 connected electrically to the semiconductor element 1 and placed between the second heat sink 14 and the chassis member 4; and the heat-conductive sheet 33 placed between the second heat sink 14 and the chassis member 4 in a manner as being in contact with the flexible base plate 7, the second heat sink 14, and the semiconductor element 1, or with the flexible base plate 7, the chassis member 4, and the semiconductor element 1 and fixes the second heat sink 14 to the chassis member 4. This makes it possible to enhance heat dissipation performance without increasing the number of components which leads to increased costs. This also makes it possible to transfer the heat highly-efficiently from the semiconductor element 1 to the chassis member 4 and to further shorten the route for dissipating heat from the semiconductor element 1 to the chassis member 4. This also enables reduction of the number of components and lowering costs.

As described above, the electronic device according to the present embodiment can include two main routes for dissipating heat. More specifically, the route for dissipating heat can include: a route for dissipating heat from the semiconductor element 1 that is a heat source through the heat conductive component 3 to the first heat sink 11; and a route for dissipating heat from the semiconductor element 1 through the resin 12 and the flexible wiring board to the second heat sink 14. Or, the route for dissipating heat can include: a route for dissipating heat from the semiconductor element 1 that is a heat source through the heat-conductive sheet 33 to the chassis member 4; and a route for dissipating heat from the semiconductor element 1 through the resin 12 and the flexible wiring board to the second heat sink 14. Or, the route for dissipating heat can include: a route for dissipating heat from the semiconductor element 1 that is a heat source through the heat-conductive sheet 33 to the second heat sink 14; and a route for dissipating heat from the semiconductor element 1 through the resin 12 and the flexible wiring board to the chassis member 4. As a result, since heat of the semiconductor element 1 is efficiently transferred to the chassis member 4, it is possible to prevent malfunction of the semiconductor element caused by heat. This allows dissipating heat from the both sides of the semiconductor element 1, making it possible to obtain sufficient allowable dissipation even when a driving power rises, or temperature rises due to chip miniaturization.

Further, merely making the heat conductive component 3 abutted to the semiconductor element 1 does not facilitate heat conduction, because the thickness of the heat conductive component 3 abutting to the semiconductor element 1 varies between each product, and heat resistance increases when the thickness increases. However, with the electronic device according to the present embodiment, the semiconductor element 1 is pressed to the heat conductive component 3 in the concave portion 11a of the first heat sink 11 by the second heat sink 14, allowing the thickness t of the heat conductive component 3 to be thin and stabilized. Accordingly, it is possible to further reduce heat resistance and to prevent malfunction of the semiconductor element 1 caused by heat.

Further, in the electronic device according to the present embodiment, the flexible wiring board is fixed on the chassis member 4 in a manner so that the first heat sink 11 and the second heat sink 14 nips the flexible wiring board. Accordingly, it is possible to prevent the flexible wiring board attached with a double-faced tape or the like from removing from the metal plate (heat sink) due to mechanical stress caused by strain at the time of mounting. As a result, it is possible to prevent malfunction due to increased heat resistance that is caused because, when the flexible wiring board removes, the semiconductor element 1 is lifted from the concave portion 11a of the first heat sink 11 and the thickness of the heat conductive component 3 becomes greater. Thus, it is possible to prevent malfunction of the semiconductor element due to mechanical reason.

Further, with the electronic device according to the present embodiment, it is possible to take a measure against noise or EMI by fixing with a screw in a manner so that the second heat sink 14 comes in contact with an exposed portion of a copper wiring pattern of the flexible wiring board connected to a ground terminal of the semiconductor element 1. This eliminates the need to place the copper wiring pattern of the flexible wiring board on the heat sink with a screw dedicated to ground placing as in the conventional techniques, allowing lowering costs.

It is to be note that, in the above-described embodiments, the top surfaces of the boss portion and the protrusion are even and come in contact with the heat sink with their entire surfaces. Further, the heat sink and the chassis member are plates made of highly heat conductive material such as metal or ceramic. Further, although the electronic device is mounted in the plasma display apparatus in the above-described embodiments, the electronic device may be mounted in a liquid crystal display apparatus or an organic EL display. Furthermore, the electronic device is mounted in the plasma display apparatus and the base plate is a chassis member with heat dissipation capabilities to which a panel or a wiring board can be attached, according to the above-described embodiments. However, in the case where the electronic device is mounted in an apparatus other than the plasma display apparatus, the base plate may be a housing, a heat sink, or the like. Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is useful for electronic devices, and in particular, for electronic devices that include a driving circuit of plasma display apparatuses.

What is claimed is:

1. An electronic device comprising:
a heat sink including a front surface having a concave portion and a back surface opposite to the front surface;
a heat conductive component placed in said concave portion, said heat conductive component being in contact with said heat sink;
a semiconductor element placed in said concave portion, said semiconductor element being in contact with said heat conductive component;
a wiring component electrically connected to said semiconductor element and placed on the front surface of said heat sink; and
a base plate having a surface, wherein
the heat sink is fixed to the base plate with the back surface of the heat sink facing the base plate.

2. The electronic device according to claim 1,
wherein an entire surface of the back surface of the heat sink is in contact with said base plate.

3. The electronic device according to claim 1,
wherein the heat sink is fixed to the base plate by a screw.

4. The electronic device according to claim 3, wherein:
said heat sink includes a first threaded hole around said concave portion, said first threaded hole penetrating said heat sink,
said base plate includes a second threaded hole, and
said heat sink is fixed to said base plate by threading said screw through said first threaded hole and said second threaded hole.

5. The electronic device according to claim 4, wherein:
said first threaded hole includes two threaded holes disposed on respective sides of said concave portion,
said second threaded hole includes two threaded holes, and
said screws includes two screws.

6. The electronic device according to claim 5, wherein:
said base plate includes a convex portion on the surface, said convex portion including said second threaded hole, and
said heat sink is fixed to said base plate such that said convex portion comes in contact with the back surface of said heat sink.

7. The electronic device according to claim 1, wherein:
said base plate includes a convex portion on the surface, and
said heat sink is fixed to said base plate such that said convex portion comes in contact with the back surface of said heat sink.

8. The electronic device according to claim 7, wherein:
said convex portion of the base plate includes first and second convex portions,
said base plate further includes a third convex portion disposed between said first and second convex portions, said third convex portion protruding toward said heat sink,
a height of said third convex portion from the surface of said base plate is greater than a height of said first or second convex portions from the surface of said base plate, and
said heat sink is fixed to said base plate such that said third convex portion comes in contact with the back surface of said heat sink.

9. The electronic device according to claim 1, wherein:
said heat sink, said semiconductor element, and an opening of said concave portion have a rectangular shape when viewed from a front surface side of said heat sink, and
said concave portion is formed so that a longitudinal side of said opening is parallel to a longitudinal side of said heat sink, and said semiconductor element is placed so that a longitudinal side of said semiconductor element is parallel to the longitudinal side of said opening.

10. The electronic device according to claim 1,
wherein said wiring component is a flexible wiring board.

11. The electronic device according to claim 1, wherein:
said wiring component includes a wire protruding toward an opening of said concave portion,
said semiconductor element includes an electrode electrically connected to a protrusion of said wire, and
the electronic device further comprises a protection resin that coats a portion of said electrode of said semiconductor element and fixes said semiconductor element in said concave portion, said portion being in contact with said protrusion.

12. An electronic device comprising:
a first heat sink including a front surface having a concave portion and a back surface opposite to the front surface;
a heat conductive component placed in said concave portion, said heat conductive component being in contact with said first heat sink;
a semiconductor element placed in said concave portion, said semiconductor element being in contact with said heat conductive component;
a wiring component electrically connected to said semiconductor element and placed on the front surface of said first heat sink;
a second heat sink having a front surface and a back surface opposite to the front surface, and placed on the front surface of said first heat sink with the front surface of the second heat sink facing the front surface of the first heat sink, said second heat sink being in contact with said wiring component; and
a base plate having a surface on which said first heat sink and said second heat sink are fixed.

13. The electronic device according to claim 12, wherein said first heat sink and said second heat sink are fixed by a screw.

14. The electronic device according to claim 12, further comprising a screw, wherein:
said first heat sink includes a first threaded hole around said concave portion, said first threaded hole penetrating said first heat sink,
said base plate includes a second threaded hole formed on the surface,
said second heat sink includes a third threaded hole penetrating said second heat sink, and
said first heat sink and said second heat sink are fixed to said base plate by threading said screw through said first threaded hole, said second threaded hole, and said third threaded hole.

15. The electronic device according to claim 14, wherein:
said first threaded hole includes two threaded holes disposed on respective sides of said concave portion,
said second threaded hole includes two threaded holes,
said third threaded hole includes two threaded holes, and
said screw includes two screws.

16. The electronic device according to claim 12, wherein said base plate includes a convex portion on the surface, said convex portion including said second threaded hole, and
said first heat sink and said second heat sink are fixed to said base plate such that said convex portion comes in contact with the back surface of said first heat sink or the back surface of said second heat sink.

17. The electronic device according to claim 12, wherein:
said base plate includes a convex portion on the surface, and
said first heat sink and said second heat sink are fixed to said base plate such that said convex portion comes in contact with the back surface of said first heat sink or the back surface of said second heat sink.

18. An electronic device comprising:
a heat sink;
a base plate having a surface on which said heat sink is fixed;
a semiconductor element placed between said heat sink and said base plate;
a wiring component electrically connected to said semiconductor element and placed between said heat sink and said base plate; and
a heat conductive component placed between said heat sink and said base plate and fixes said heat sink to said base plate, said heat conductive component being in contact with said heat sink, said wiring component and said semiconductor element or in contact with said semiconductor element, said wiring component and said base plate.

19. The electronic device according to claim 18, wherein:
said wiring component includes a plurality of wiring components, and
said heat sink is shared by said plurality of wiring components.

20. The electronic device according to claim 18, wherein:
said heat sink has external dimensions larger than external dimensions of said wiring component, and
said heat sink includes an edge protruding toward outside said wiring component.
